(19) United States
(12) Patent Application Publication
(10) Pub. No.: US 2012/0056228 A1
(43) Pub. Date: Mar. 8, 2012

(54) LED CHIP MODULES, METHOD FOR PACKAGING THE LED CHIP MODULES, AND MOVING FIXTURE THEREOF

(75) Inventors: Ray-Hua Horng, Taichung City (TW); Jhih-Sin Hong, Taichung City (TW); Shih-Feng Shao, New Taipei City (TW); Heng Liu, Sunnyvale, CA (US)

(73) Assignees: PHOSTEK, INC., Taipei City (TW); NATIONAL CHENG KUNG UNIVERSITY, Tainan City (TW)

(21) Appl. No.: 13/226,147

(22) Filed: Sep. 6, 2011

Related U.S. Application Data
(63) Continuation-in-part of application No. 13/226,067, filed on Sep. 6, 2011.

(30) Foreign Application Priority Data
Sep. 7, 2010 (TW) 099130225
Jul. 15, 2011 (TW) 100125235

(51) Int. Cl. H01L 33/60; B25J 15/06

(52) U.S. Cl. 257/98; 438/27; 294/184; 257/E33.072

(57) ABSTRACT

A method for packaging LED chip modules is provided. First, a first sacrificial layer is disposed on a substrate. Afterwards, LED chips are synchronously disposed on the first sacrificial layer before the first sacrificial layer cures. Next, a first material, a second sacrificial layer, and a second material are used to form a support layer on the first sacrificial layer. The first sacrificial layer and the second sacrificial layer are then removed, so that LED chip modules are obtained, wherein each LED chip module has a corresponding support layer. Furthermore, a moving fixture is provided to synchronously remove chips from a wafer and dispose them on the sacrificial layer.

### CROSS-REFERENCES TO RELATED APPLICATIONS

This application is a continuation in part of application Ser. No. 13/226,067, filed Sep. 6, 2011, which claims priorities to Taiwan, R.O.C. patent application No. 099130225, filed Sep. 7, 2010 and No. 100125235, filed Jul. 15, 2011, which is hereby incorporated by reference herein.

### FIELD OF THE INVENTION

The present invention is related to a package method and related apparatus, particularly to a method for packaging LED chip modules and moving fixture thereof.

### BACKGROUND

Nowadays, methods for packaging LED chips are substantially similar to those for packaging general chips. FIG. 1 is a cross-section view illustrating a conventional LED chip module.

Referring to FIG. 1, a silver glue 11 is dispensed into a pre-produced packaging base 12 during the process of packaging an LED chip 100. Subsequently, but before the silver glue 11 dries and cures, individual LED chips 100 retrieved via vacuum suction from a wafer attached to a blue tape are placed, one at a time, onto the packaging base 12. Afterwards, the silver glue 11 is cured by means of baking, such that the LED chip 100 is stuck on the packaging base 12 by means of the silver glue 11, so as to obtain the LED chip module 1 as illustrated in FIG. 1. Then, an LED light source module (not shown) is obtained by carrying out processes, such as wire bonding, optical adhesive filling, cutting and other conventional steps.

While the above-mentioned process is suitable for mass production of LED chip modules, the process is burdened by several serious drawbacks. One significant limitation is that as improvements are made allowing LED chips 100 to become smaller, a mismatch is created between the pre-produced packaging base 12 and the chip 100. The volume of the pre-produced packaging base 12 is incapable of being reduced because of the machining existing in the packaging base.

In view of the above, a novel technology for packaging LED is provided in Taiwan Patent Application No. 096141685 to address the above-mentioned problem. In this manner, the volume of the packaged LED chip module may be reduced effectively, and brightness is improved at the same time.

However, other problems remain with mass production of LEDs. One problem occurs when LED chips are embedded, one at a time, into a recently deposited or coated layer of “photoresist.” The photoresist layer may dry and cure before all of the LED chips are embedded into the layer.

### SUMMARY OF THE INVENTION

The present invention provides a method for packaging LED chip modules that better facilitates their mass production.

The present invention provides a moving fixture, used in the method for packaging LED chip modules, suitable for moving multiple chips synchronously.

The present invention provides a method for packaging LED chip modules, suitable for mass-producing multiple LED chip modules. Each of the LED chip modules comprises at least one LED chip. This method for packaging comprises: disposing a first sacrificial layer on a substrate; synchronously disposing multiple LED chips on the first sacrificial layer before the first sacrificial layer has been cured; forming a support layer from a first material, a second sacrificial layer, and a second material on the cured first sacrificial layer, wherein a module pattern is defined in the second sacrificial layer, and the support layer comprises the first material and the second material; and removing the first sacrificial layer and the module pattern, so as to obtain the LED chip modules, wherein each of the LED chip modules comprises the corresponding support layer.

The present invention provides an LED chip module, comprising at least one LED chip having a substrate and a plurality of epitaxial layers; an optical cup having a inside bottom and an upper edge, the optical cup carrying the at least one LED chip via the inside bottom; the upper edge of the optical cup comprising at least one enclosed groove or at least one enclosed flange surrounding the at least one LED chip; at least one insulating layer located on the enclosed groove or enclosed flange; two conductive layers located on the insulating layer; two wires, each connected between the corresponding conductive layer and the at least one LED chip; and a encapsulation structure covering the at least one LED chip, in which the range formed with the encapsulation structure is restricted by the enclosed groove or enclosed flange, and each of the two wires is extended towards the outside of the encapsulation via the corresponding conductive layer.

In one embodiment of the present invention, the thickness of the first sacrificial layer is not larger than the height of the LED chip in the step of disposing a first sacrificial layer.

In one embodiment of the present invention, the method for packaging further comprises a step of arranging chips and a step of moving chips prior to the step of synchronously disposing chips. In the step of placing and arranging chips, each of the LED chips is placed into a corresponding accommodating location in a carrying disc of a moving fixture. In the step of moving chips, the multiple LED chips placed in the carrying disc are moved synchronously and correspondingly.

In one embodiment of the present invention, in the step of arranging chips, each of the multiple LED chips is removed chip-by-chip from a wafer attached on a blue tape and comprising the LED chips, using vacuum suction, sticky adhesion, magnetic adhesion, gripping or snapping, and then placed in each of the accommodation locations, arranged in a matrix form, in the carrying disc.

In one embodiment of the present invention, the moving fixture comprises multiple suction tips, further comprising the step of synchronously sucking the LED chips through vacuum suction using said suction tips, and then placing them, synchronously, in the carrying disc.

In one embodiment of the present invention, the method for packaging further comprises a step of sticking chips subsequent to the step of synchronously disposing chips. In the step of sticking chips, the first sacrificial layer is cured so as to stick the LED chips to the substrate.

In one embodiment of the present invention, the step of forming a support layer comprises steps as follows: forming a reflector film from the first material on the cured first sacrificial layer, defining the module pattern on the reflector film by the second sacrificial layer to form multiple independent and exposed regions, forming a base on each of the independent and exposed regions from the second material, in which a region of the reflector film corresponding to each of the bases is a reflector, and the reflectors and the bases together form the support layer.

In one embodiment of the present invention, the step of forming a support layer comprises steps as follows: defining the module pattern by the second sacrificial layer on the cured first sacrificial layer to form multiple independent and exposed regions, forming a reflector and a base on each of the independent and exposed regions from the first material and the second material in turn, in which the reflectors and the bases together form the support layer.

In one embodiment of the present invention, each of the LED chip modules comprises an optical cup constituted by a predetermined zone of a corresponding support layer, and a predetermined number of LED chips located in the optical cup.

In one embodiment of the present invention, each of the first sacrificial layer and the second sacrificial layer is a photoresistant layer.

The present invention provides a moving fixture, suitable for moving multiple LED chips synchronously. The moving fixture comprises an upper molding board, a lower molding board, and a carrying disc. The upper molding board is provided with a vacuum chamber. The lower molding board is provided with multiple through-holes. The through-holes pass through a body of the lower molding board and communicate with the vacuum chamber. The carrying disc is provided with multiple accommodating locations, into which the LED chips are placed. In this connection, the LED chips placed in the carrying disc are adapted to be sucked synchronously by the moving fixture using vacuum suction.

In one embodiment of the present invention, the moving fixture further comprises a vacuum seal ring. The vacuum seal ring is clamped between the upper molding board and the lower molding board, in which the vacuum chamber of the upper molding board is located within the enclosing range of the vacuum seal ring.

In one embodiment of the present invention, the vacuum chamber and a vacuum piping are connected with each other.

In one embodiment of the present invention, the carrying disc comprises at least one first locator.

In one embodiment of the present invention, the lower molding board comprises at least one second locator. The second locator is cooperated with the first locator, in such a way that the first and second locators are positioned perpendicularly to each other.

In one embodiment of the present invention, the moving fixture further comprises multiple suction tips. The suction tips are corresponding and communicating with respective ones of the through-holes extending outwardly from an external surface of the body of the lower molding board. Here, the LED chips placed in the carrying disc are sucked synchronously by the suction tips using vacuum suction.

In one embodiment of the present invention, the suction tips and accommodating locations of the carrying disc are arranged correspondingly with each other in a matrix form.

Based on the above, in the embodiments of the present invention, a special fixture is used to position chips all at once, so as to eliminate the problem of incapability of actual mass-production resulted from only positioning chips chip-by-chip being allowed presently.

For better understanding of above-mentioned features and advantages, the present invention will be described by specific embodiments in conjunction with accompanying drawings in detail as follows.

### BRIEF DESCRIPTION OF DRAWINGS

FIG. 1 is a cross-section view illustrating a conventional LED chip module.

FIG. 2 is a flow chart of a method for packaging mass-produced LED chip modules according to one embodiment of the present invention.

FIG. 3 is a top diagram of the LED chip module produced by the method for packaging mass-produced LED chip modules illustrated in FIG. 2.

FIG. 4 is a diagram showing the section along V-V in FIG. 3.

FIG. 5 shows the step of disposing photoresist of the method for packaging mass-produced LED chip modules according to one embodiment of the present invention.

FIG. 6 shows the step of arranging chips of the method for packaging mass-produced LED chip modules according to one embodiment of the present invention.

FIG. 7 shows the step of sucking chips by a fixture of the method for packaging mass-produced LED chip modules according to one embodiment of the present invention.

FIG. 8 shows the structure of fixture used in carrying out the step of sucking chips by a fixture

FIG. 9 shows the step of synchronously disposing chips of the method for packaging mass-produced LED chip modules according to one embodiment of the present invention.

FIG. 10 shows the step of forming a support layer of the method for packaging mass-produced LED chip modules according to one embodiment of the present invention.

FIG. 11 shows the step of forming a support layer of the method for packaging mass-produced LED chip modules according to another embodiment of the present invention.

FIG. 12 shows the step of forming a enclosed groove of the method for packaging mass-produced LED chip modules according to one embodiment of the present invention.

FIG. 13 shows the step of forming a enclosed flange of the method for packaging mass-produced LED chip modules according to one embodiment of the present invention.

FIG. 14 shows the step of encapsulation of the method for packaging mass-produced LED chip modules according to one embodiment of the present invention.

FIG. 15 shows the step of encapsulation of the method for packaging mass-produced LED chip modules according to another embodiment of the present invention.

FIG. 16 shows one embodiment of the present invention, using a substrate having at least one concave structure.

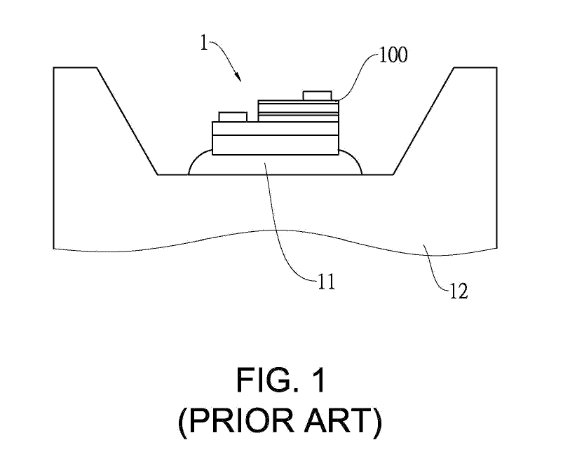

### DETAILED DESCRIPTION OF THE INVENTION

In the exemplified embodiments of the present invention, a method for packaging mass-produced LED chip modules, used for mass-producing the LED chip modules including optical cups in practice, is provided. In this connection, the method for packaging mass-produced LED chip modules comprises steps of disposing sacrificial layer, arranging chips, sucking chips by a fixture, synchronously disposing chips, sticking chips, forming a support layer, and removing sacrificial layer for obtaining finished product, so as to mass-produce the LED chip modules.

In the step of disposing sacrificial layer, a layer of first photoresist (i.e., a first sacrificial layer), having a thickness not larger than the height of the LED chip, is disposed onto a temporary substrate.

In the step of arranging chips, each of the LED chips is removed from a blue tape chip-by-chip by means of vacuum suction, sticky adhesion, magnetic adhesion, gripping or snapping, when a wafer is attached to the blue tape and cut into multiple LED chips. It is followed by placing each of the removed LED chips, in turn, into each accommodating location of a carrying disc having accommodating locations in a matrix form.

In the step of sucking chips by a fixture, a fixture having numerous suction tips is used to suck the numerous LED chips located in the carrying disc via the suction tips one-to-one at the same time in a way of vacuum suction.

In the step of synchronously disposing chips, the fixture is moved to press the sucked numerous LED chips all at once into the first photoresist at the same time, before the first photoresist is not cured yet, in such a way that the first photoresist may be formed as a continuously smooth concave pattern towards the temporary substrate, from the contact area with each of the LED chips, due to surface tension.

In the step of sticking chips, the first photoresist formed with numerous concave arc patterns is cured, so as to stick the LED chips.

In the step of forming a support layer, a support layer is formed on the cured first photoresist, and a module pattern, over the predetermined number of the LED chips, is defined in cooperation with the second photoresist (i.e., a second sacrificial layer), so as to obtain the numerous LED chip modules, connected to the temporary substrate by means of the first photoresist, respectively, in which each of the LED chip modules is provided with an optical cup constituted by a predetermined zone of the support layer, and a predetermined number of the LED chips located in the optical cup.

In the step of removing sacrificial layer for obtaining finished products, the first photoresist and the module pattern are removed, in such a way that the temporary substrate and the LED chip modules are separated, for obtaining the numerous LED chip modules.

In the exemplified embodiments of the present invention, the effect consists in: mass-producing the LED chip modules including the optical cups in seven steps in cooperation with the fixture in practice.

In the following description, similar elements indicated by the same number. The description of each embodiment is used for illustrating the specific embodiment capable of being embodied by the present invention with reference to accompanying drawings. The terms for direction, such as “upper”, “lower”, “front”, “rear”, “left”, “right”, and etc., for example, mentioned in the present invention is only the direction with reference to the accompanying drawings. Therefore, these terms for direction are used for describing, not for restricting the present invention.

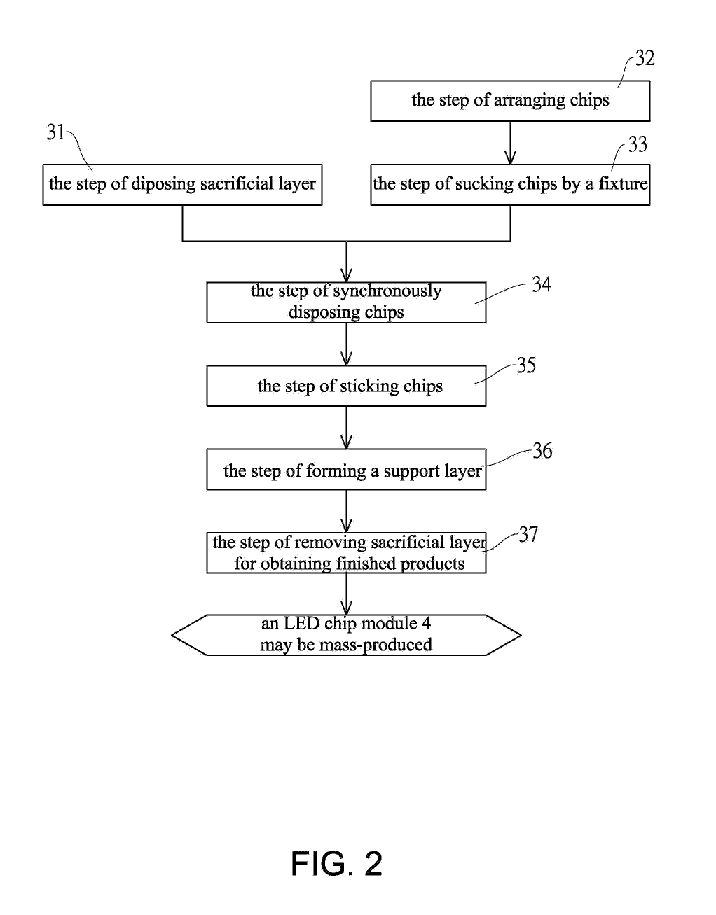

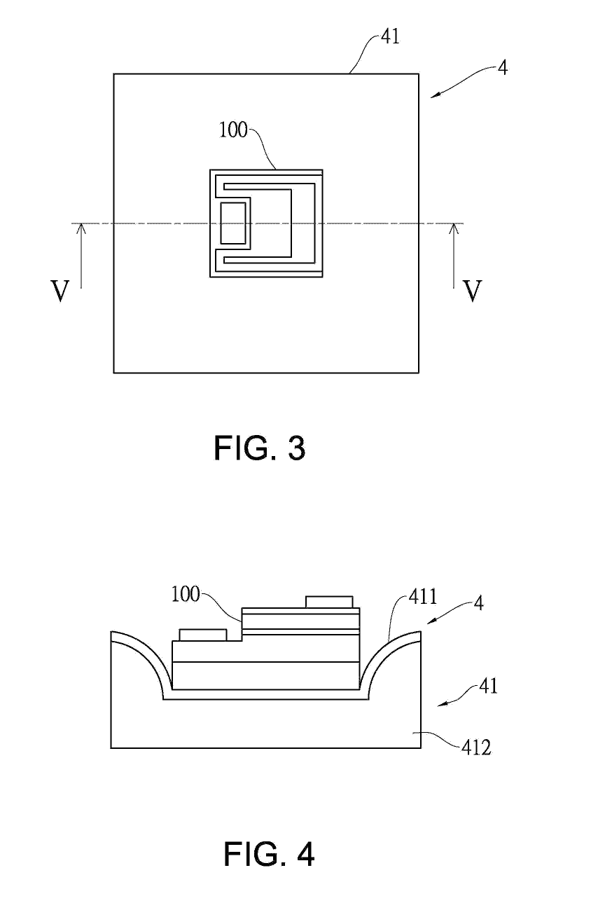

FIG. 2 is a flow chart of a method for packaging mass-produced LED chip modules according to one embodiment of the present invention. In this embodiment, referring to FIG. 2, the method for packaging mass-produced LED chip modules comprises seven processes including steps of disposing sacrificial layer 31, arranging chips 32, sucking chips by a fixture 33, synchronously disposing chips 34, sticking chips 35, forming a support layer 36, and removing sacrificial layer for obtaining finished products 37. Then, an LED chip module 4, as shown in FIGS. 3 and 4 may be mass-produced in practice.

FIG. 3 is a top diagram of the LED chip module produced by the method for packaging mass-produced LED chip modules illustrated in FIG. 2. Moreover, FIG. 4 is a diagram showing the section along V-V in FIG. 3.

In this embodiment, referring to FIGS. 3 and 4, the LED chip module 4 comprises an optical cup 41, and an LED chip 100 located in the optical cup 41. In this connection, the optical cup 41 is provided with a reflector 411, constituted by a material of high reflectivity (i.e., a first material), for reflecting light, and a base 412, constituted by a material of high thermal conductivity (i.e., a second material), for heat dissipation. Moreover, the LED chip 100 is a general mass-produced LED chip having a structure widely known to those skilled in this art and should not be detailed herein. The LED chip module 4 should be subjected to processes, such as wire bonding, optical adhesive filling, and etc., successively to form an LED light source module capable of radiating light when electric power is provided. These subsequent processes are not related to the present invention essentially, and then should not be described further herein.

Exemplified embodiments of the method for packaging mass-produced LED chip modules illustrated below will be more clear when they are read in conjunction with the above-mentioned description of the LED chip module 4.

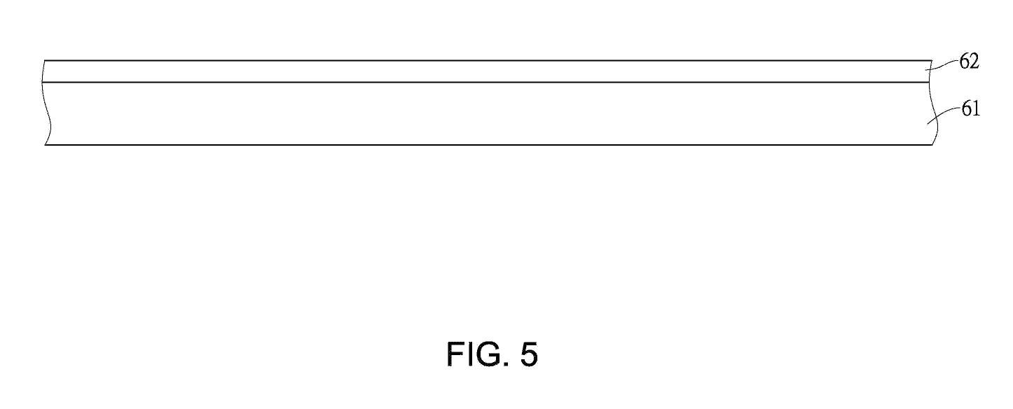

FIG. 5 shows the step of disposing photoresist of the method for packaging mass-produced LED chip modules according to one embodiment of the present invention. In the present invention, referring to FIGS. 2 and 5, the step of disposing photoresist 31 is carried out firstly to coat a layer of first photoresist 62, having a thickness not larger than the height of the LED chip 100, onto a temporary substrate 61.

At this time, the steps of arranging chips 32 and sucking chips by a fixture 33 are carried out synchronously.

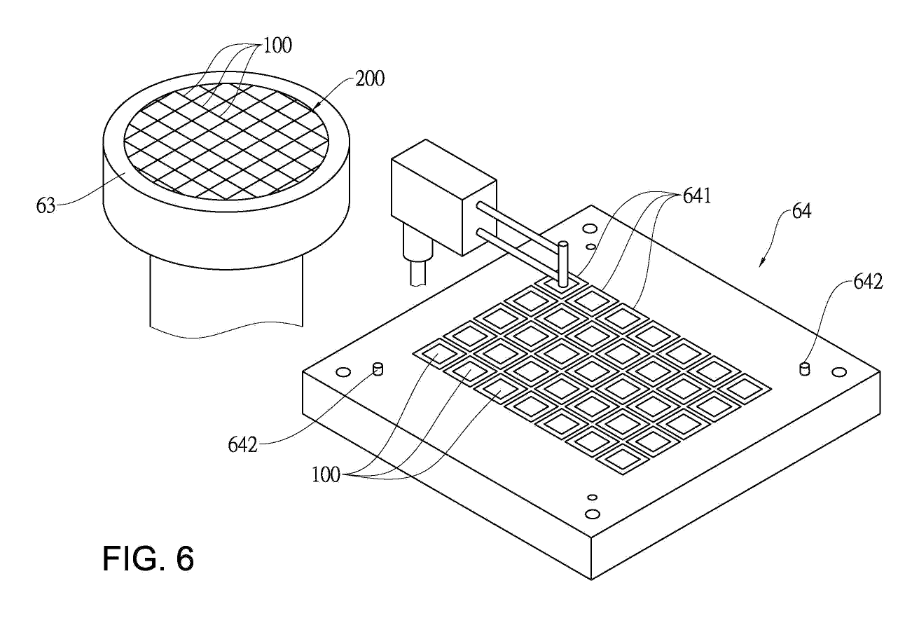

FIG. 6 shows the step of arranging chips of the method for packaging mass-produced LED chip modules according to one embodiment of the present invention. In the present invention, referring to FIGS. 2 and 6, the step of arranging chips 32 is carried out to remove each of the LED chips 100 from a blue tape 63 chip-by-chip by means of vacuum suction, sticky adhesion, magnetic adhesion, gripping or snapping, when a wafer 200 is attached to the blue tape 63 and cut into multiple LED chips 100. It is followed by placing each of the removed LED chips 100, in turn, into each accommodating location 641 of a carrying disc 64 having accommodating locations 641 in a matrix form. In the present invention, the carrying disc 64 is provided, for example, with a plurality of first locators 642, used for positioning.

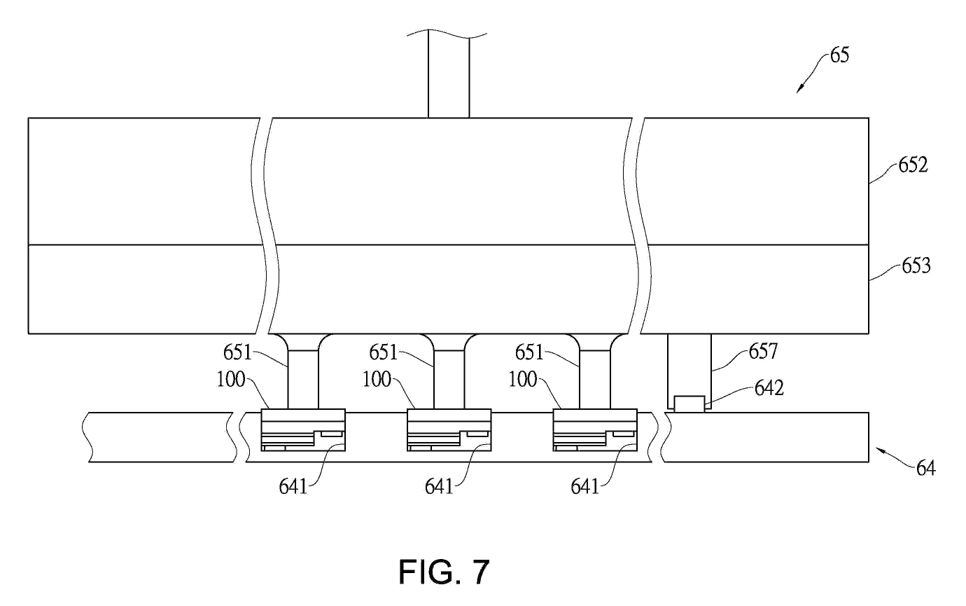

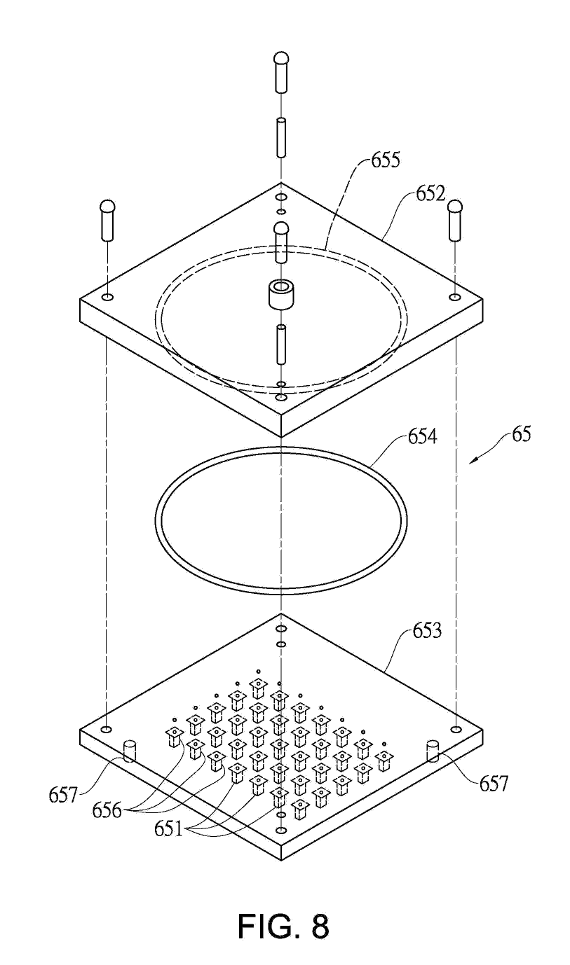

FIG. 7 shows the step of sucking chips by a fixture of the method for packaging mass-produced LED chip modules according to one embodiment of the present invention. FIG. 8 shows the structure of fixture used for carrying out the step of sucking chips by a fixture. In this embodiment, referring to FIGS. 2, 7 and 8, the step of sucking chips by a fixture 33 is then carried out. In this connection, a fixture 65 having numerous suction tips 651 (and a one-to-one correspondence with the LED chips 100) is used to suck the numerous LED chips 100 located in the carrying disc 64 via the suction tips 651 at the same time using vacuum suction. In this case, the fixture 65 comprises, for example, an upper molding board 652 and a lower molding board 653 matching each other, as well as a vacuum seal ring 654 clamped between the upper and lower molding boards 652 and 653.

In this embodiment, the upper molding board 652 is provided with a passing vacuum chamber 655 connectable to the vacuum piping (not shown) in the production line and located within the enclosing range of the vacuum seal ring 654. The lower molding board 653 is further provided with numerous through-holes 656 passing through the board body and communicated with the vacuum chamber 655. Moreover, the suction tips 651 are in communication with respective and corresponding through-holes 656, projecting and extending downwardly from the lower external surface of the board body.

In addition, the lower molding board 653 of the fixture 65 is provided with a plurality of second locators 657 matched and positioned perpendicularly to the first locators 642. Thereby, the fixture 65 is allowed to suck each of the LED chips 100 in the carrying disc 64 precisely by means of each of the corresponding suction tips 651, when its second locators 657 are positioned perpendicularly to the first locators 642 of the carrying disc 64.

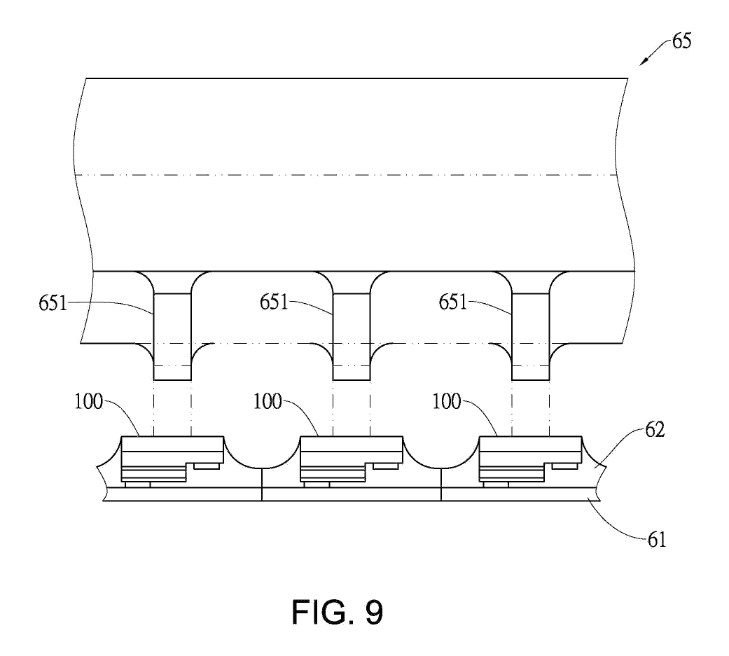

FIG. 9 shows the step of synchronously disposing chips of the method for packaging mass-produced LED chip modules according to one embodiment of the present invention. In this embodiment, referring to FIGS. 2 and 9, the step of synchronously disposing chips 34 is then carried out. The fixture 65 is moved to press the sucked numerous LED chips 100 into the first photoresist 62 at the same time, before the first photoresist 62 is cured, in such a way that the first photoresist 62 is formed as a continuously smooth concave pattern towards the temporary substrate 61, from the contact area with each of the LED chips 100, due to surface tension.

Afterwards, a step of sticking chips 35 is carried out, and the first photoresist 61 formed with numerous concave arc patterns is thus cured. In the step of sticking chips 35, the first photoresist 61 is cured by means of baking, for example.

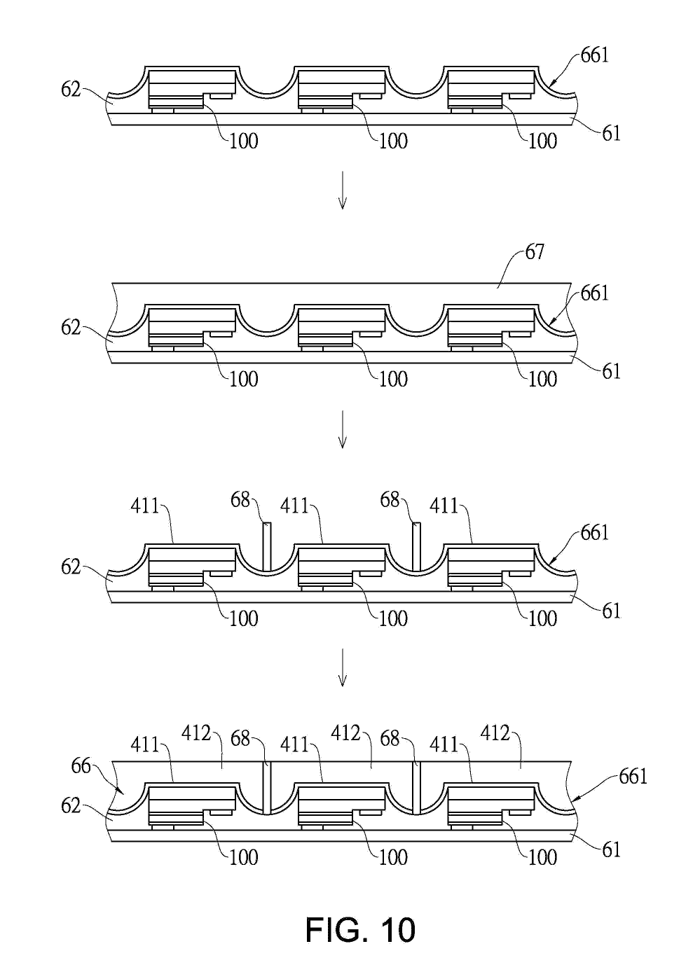

FIG. 10 shows the step of forming a support layer of the method for packaging mass-produced LED chip modules according to one embodiment of the present invention. In this embodiment, referring to FIGS. 2, 4 and 10, the step of forming a support layer 36 is then carried out, so as to form a support layer 66 on the cured first photoresist 62, and define a module pattern 68, over the predetermined number of the LED chips 100, in cooperation with the second photoresist 67. Then, the numerous LED chip modules 4, connected to the temporary substrate 61 by means of the first photoresist 62, respectively, are obtained. In this connection, each of the LED chip modules 4 is provided with the optical cup 41 constituted by a predetermined zone of the support layer 66, and the LED chip 100 located in the optical cup 41.

In the step of forming a support layer 36, in more detail, the cured first photoresist 62 is firstly plated thereon with a material having high reflectivity to form a reflector film 661. On the reflector film 661, subsequently, there is disposed with the liquid second photoresist 67. Afterwards, the second photoresist 67 is defined as the module pattern 68 by means of lithography process. At this time, the surface of a reflector film 661 is formed with numerous independent and exposed regions by means of the module pattern 68. Subsequently, the surface of the reflector film 661 is further thickened to form numerous bases 412 by means of a material of high thermal conductivity (for instance, copper). In this case, a region of the reflector film 661 corresponded by each of the bases is just a reflector 411. In this embodiment, the support layer 66 is constituted by the reflector 411 and the base 412, for example, so as to obtain the multiple LED chip modules 4, connected with the first photoresist 62 and temporary substrate 61, respectively.

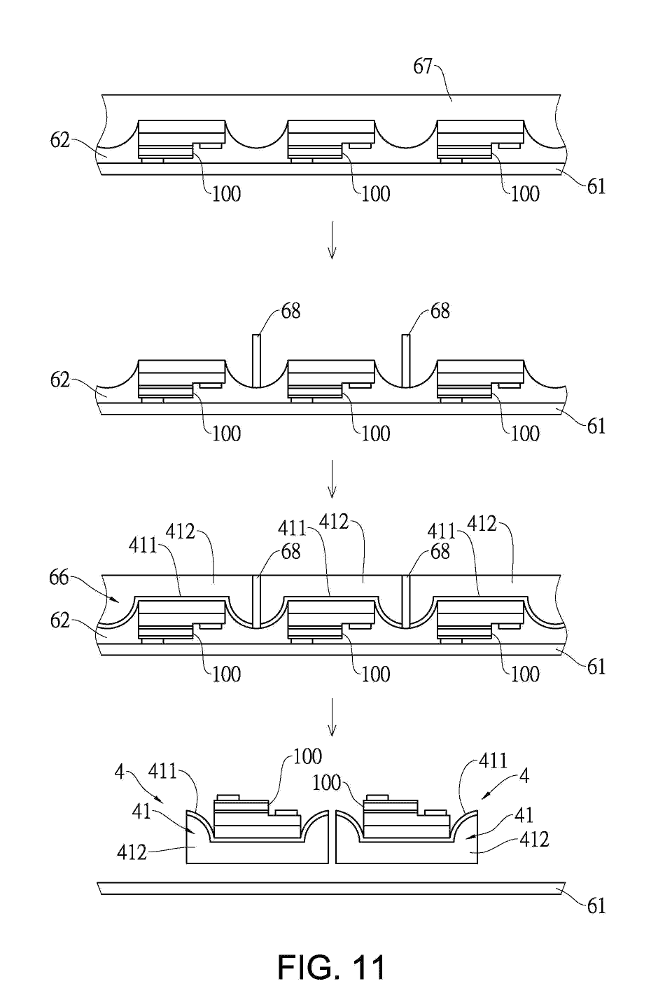

FIG. 11 shows the step of forming a support layer of the method for packaging mass-produced LED chip modules according to another embodiment of the present invention. Referring to FIGS. 2, 4 and 11, the step of forming a support layer in this embodiment and that shown in FIG. 10 are similar, with the difference therebetween as follows.

In the step of forming a support layer 36 of this embodiment, the cured first photoresist 62 is firstly disposed with the liquid second photoresist 67, and this second photoresist 67 is then defined as the module pattern 68 by means of lithography process, to form multiple independent and exposed regions. In each of these independent and exposed regions, afterwards, the reflector 411 and the base 412 are formed from the material of high reflectivity and the material of high thermal conductivity in turn, in which the reflector 411 and the base 412 form the support layer 66 together.

Subsequently, referring to FIGS. 2, 3 and 4, a step of removing sacrificial layer for obtaining finished products 37 is finally carried out to remove the first photoresist 62 and the module pattern 68, in such a way that the temporary substrate 61 and the LED chip modules 4 are separated, for obtaining the numerous LED chip modules 4.

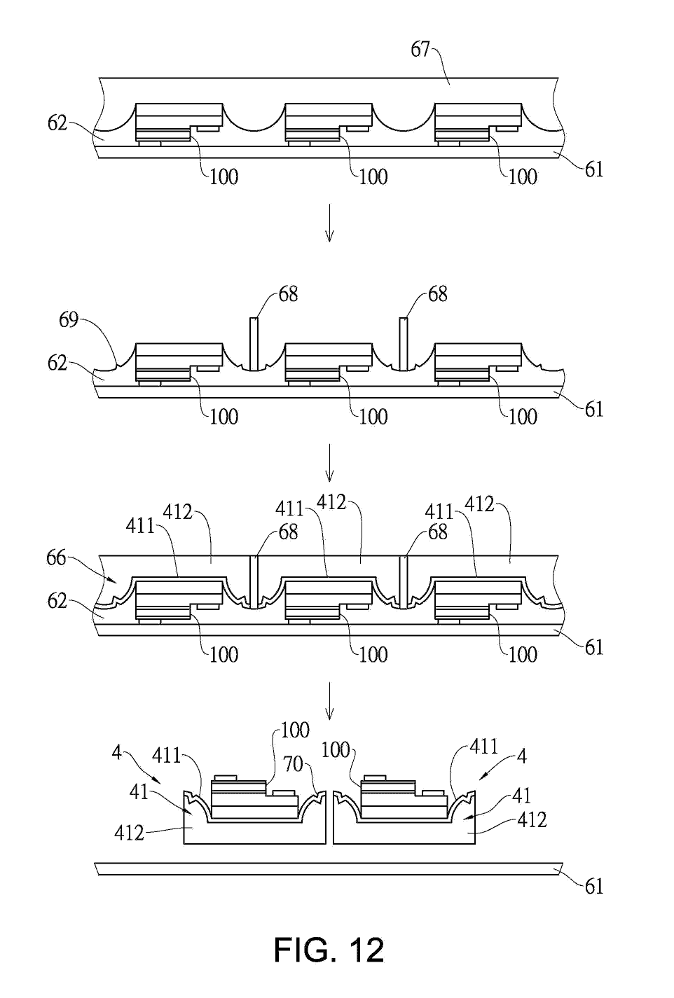

The processes, including wire bonding, encapsulation, etc., may be carried out before or after the step of removing sacrificial layer for obtaining finished products 37. An overflow of adhesive may occur, however, because the packaging adhesive often flows along the wire used for wire bonding due to surface tension, in such a way that the shape of encapsulation is changed after encapsulation, leading to a reduced light extraction efficiency. Therefore, the present invention provides another embodiment, as illustrated in FIG. 12. A sacrificial flange 69 may be further defined in the second photoresist 67 by means of lithography process, and an enclosed groove 70 may be then formed on the reflector 411 due to the sacrificial flange 69, in which the enclosed groove 70 surrounds at least one of the LED chips 100.

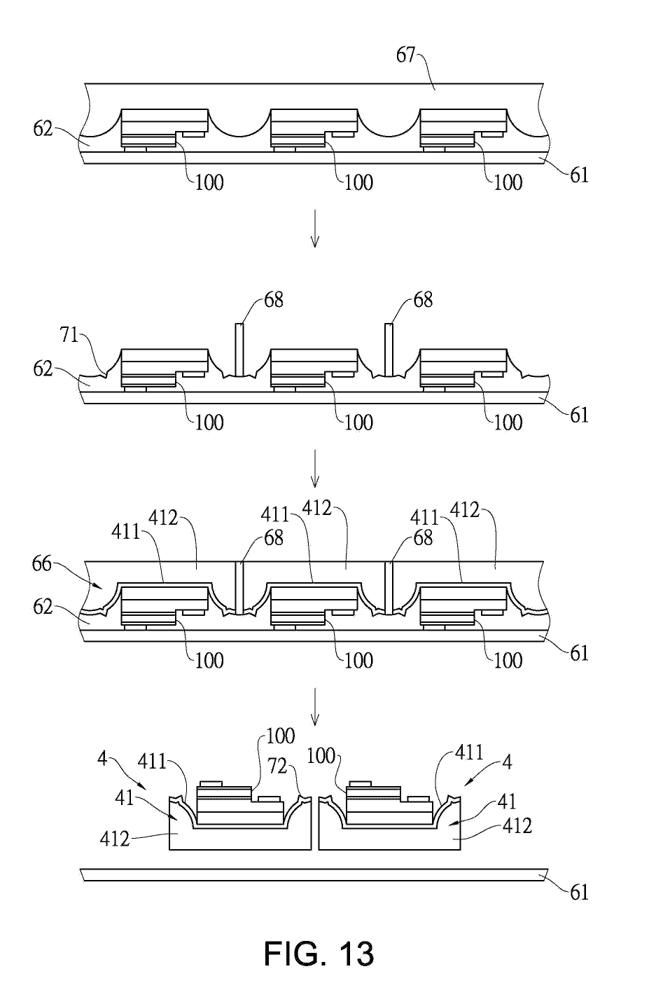

In the above-mentioned step of forming a support layer 36 of the present invention, it is also possible to define the photoresist 67 as the module pattern 68, followed by defining a sacrificial groove 71 in the first photoresist 62 by means of lithography process, as illustrated in FIG. 13. Afterwards, the reflector 411 may be then formed with an enclosed flange 72, surrounding at least one of the LED chips 100, due to the sacrificial groove 71.

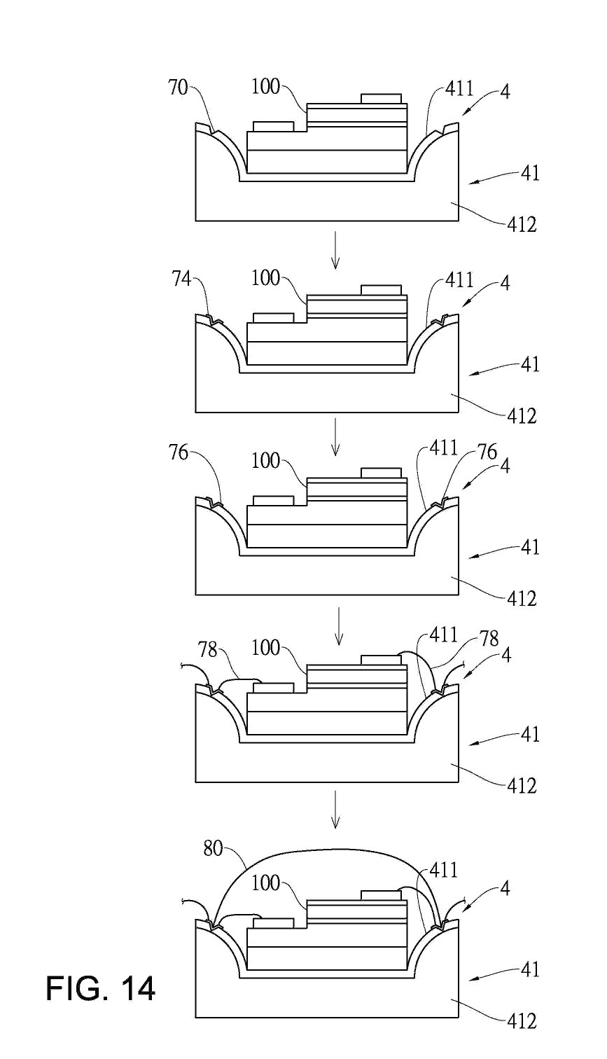

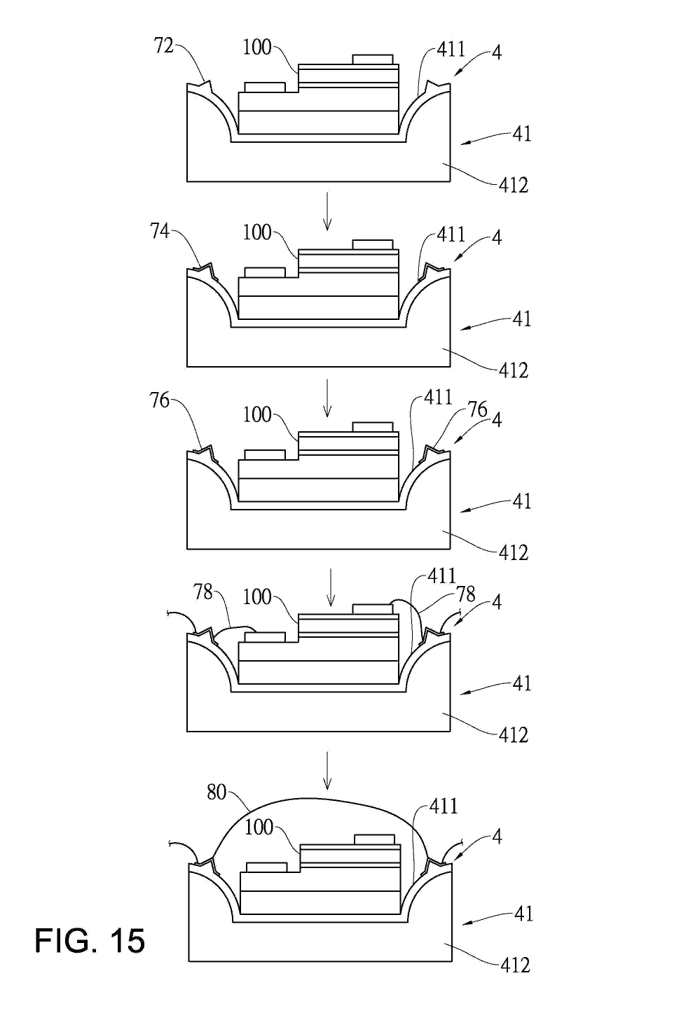

After the above-mentioned process is completed, referring to FIGS. 14 and 15, each of the LED chip modules 4 is further synchronously subjected to steps as follows: firstly, forming an insulating layer 74 on the enclosed groove 70 or the enclosed flange 72; afterwards, forming two conductive layers 76 on the insulating layer 74, and then connecting each of two wires 78 between the corresponding conductive layer 76 and at least one of the LEDs 100; finally, forming a encapsulation 80 on at least one of the LEDs 100, in which the area formed from the encapsulation 80 may be restricted by the enclosed groove 70 or the enclosed flange 72, for avoiding the occurrence of overflow of adhesive. Moreover, each of the two wires 78 is extended towards the outside of the encapsulation 80 via the corresponding conductive layer 76, so as to connect to external circuits, or electrically connect to other LED chip modules.

It should be stated that, when the first photoresist 62 and the module pattern 68 are removed during the step of removing sacrificial layer for obtaining finished products 37, the local structure of the reflector film 661 covered by the module pattern 68 is etched to be removed directly due to extreme thinness of the reflector, so as to obtain the numerous independent LED chip modules 4.

It should be stated, additionally, one LED chip 100 in one optical cup 41 is described in all of the exemplified embodiments of the present invention. However, it is known to those having ordinary skill in the art that a plurality of LED chips 100 in one optical cup 41 is achieved, only the change in pattern is required for defining the second photoresist 67 as the module pattern 68. This is only a simple design of pattern change, and thus should not be detailed herein.

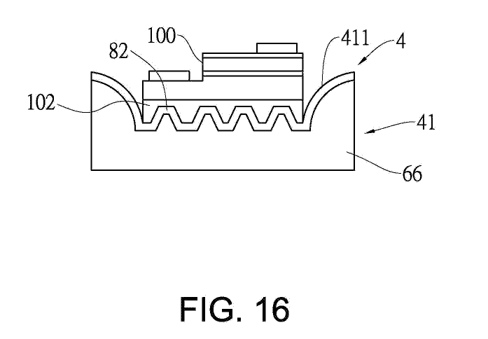

Furthermore, as illustrated in FIG. 16, a substrate 102 of the at least one LED chip 100 may be further formed with at least one concave structure 82, into which the support layer 66 grows possibly, facilitating the enlargement of the contact area between the support layer 66 and the substrate 102. Thereby, the enhancement of heat dissipation, and more stable connection between the support layer 66 and the substrate 102 of the LED chip 100 are thus obtained.

In one embodiment of the present embodiment, there is provided an LED chip module, comprising at least one LED chip 100 having a substrate and a plurality of epitaxial layers; an optical cup 41 having a inside bottom and an upper edge, the optical cup 41 carrying at least one LED chip 100 via the inside bottom; the upper edge of the optical cup 41 comprising at least one enclosed groove 70 or at least one enclosed flange 72 surrounding the at least one LED chip 100; at least one insulating layer 74 located on the enclosed groove 70 or the enclosed flange 72; two conductive layers 76 located on the insulating layer 74; two wires 78, each connected between the corresponding conductive layer 76 and the at least one LED chip 100; and a encapsulation structure covering the at least one LED chip 100, in which the range formed with the encapsulation structure is restricted by the enclosed groove 70 or the enclosed flange 72, and each of the two wires 78 is extended towards the outside of the encapsulation structure via the corresponding conductive layer 76.

In one example of the present embodiment, the optical cup 41 is provided with a reflector 411 and a support layer 66, in which the substrate of at least one LED chip 100 is carried by the optical cup 41 via the reflector 411.

In another example of the present invention, the substrate of the LED chip 100 is provided with at least one concave structure 82, into which the reflector 411 and the support layer 66 grow.

To sum up, in the embodiments of the present invention, a special fixture is used to position chips all at once, for the elimination of the current problem of incapability of actual mass-production resulted from only positioning all chips chip-by-chip. Additionally, in the embodiments of the present invention, the volume of the packaged LED chip module may be reduced effectively, and brightness is improved at the same time.

Although the present invention has been disclosed by embodiments as above, the present invention is not thus restricted. A few of variations and modifications are possible for those having ordinary skill in the art without departing from the spirit and scope of the invention. Thus, the scope of the present invention should depend upon what the appended claims define.

1. A method for packaging LED chip modules, suitable for mass-producing multiple LED chip modules, each of the LED chip modules comprising at least one LED chip, said method for packaging comprising the steps of:
disposing a first sacrificial layer on a substrate;
synchronously disposing multiple LED chips on said first sacrificial layer before said first sacrificial layer has been cured;
forming a support layer from a first material, a second sacrificial layer, and a second material on said cured first sacrificial layer, wherein a module pattern is defined in said second sacrificial layer, and said support layer comprises said first material and said second material; and
removing said first sacrificial layer and said module pattern, so as to obtain said LED chip modules, wherein each of said LED chip modules comprises said corresponding support layer.

2. The method for packaging LED chip modules according to claim 1, wherein the thickness of said first sacrificial layer is not larger than the height of each of said LED chips in said step of disposing a first sacrificial layer.

3. The method for packaging LED chip modules according to claim 1, wherein, prior to said step of synchronously disposing chips, said method for packaging further comprises the steps of:
placing and arranging each of said multiple LED chips into a corresponding accommodating location in a carrying disc of a moving fixture; and
moving said multiple LED chips placed in said carrying disc synchronously and correspondingly.

4. The method for packaging LED chip modules according to claim 3, wherein, in said step of arranging chips, each of said multiple LED chips is removed chip-by-chip from a wafer attached on a blue tape and comprising said LED chips, using vacuum suction, sticky adhesion, magnetic adhesion, gripping or snapping, and then placed in each of said accommodation locations, arranged in a matrix form, in said carrying disc.

5. The method for packaging LED chip modules according to claim 3, wherein said moving fixture comprises multiple suction tips, further comprising the step of synchronously sucking said LED chips through vacuum suction using said suction tips, and then placing them, synchronously, in said carrying disc.

6. The method for packaging LED chip modules according to claim 1, wherein, subsequent to said step of synchronously disposing chips, said method for packaging further comprises:
curing said first sacrificial layer, so as to stick said LED chips to the substrate.

7. The method for packaging LED chip modules according to claim 1, wherein said step of forming a support layer comprises:
forming a reflector film from said first material on said cured first sacrificial layer;
defining said module pattern on said reflector film by said second sacrificial layer to form multiple independent and exposed regions; and
forming a base on each of said independent and exposed regions from said second material, wherein a region of said reflector film corresponding to each of said bases is a reflector, and said reflectors and said bases together form said support layer.

8. The method for packaging LED chip modules according to claim 7, wherein each of said LED chip modules comprises an optical cup constituted by a predetermined zone of said corresponding support layer, and a predetermined number of said LED chips located in said optical cup.

9. The method for packaging LED chip modules according to claim 1, wherein said step of forming a support layer comprises:
defining said module pattern by said second sacrificial layer on said cured first sacrificial layer to form multiple independent and exposed regions; and
forming a reflector and a base on each of said independent and exposed regions from said first material and said second material in turn, wherein said reflectors and said bases together form said support layer.

10. The method for packaging LED chip modules according to claim 9, wherein each of said LED chip modules comprises an optical cup constituted by a predetermined zone of said corresponding support layer, and a predetermined number of said LED chips located in said optical cup.

11. The method for packaging LED chip modules according to claim 9, wherein said reflector of each of said LED chip modules includes a enclosed groove or a enclosed flange surrounding said at least one LED chip.

12. The method for packaging LED chip modules according to claim 11, wherein each of said LED chip modules is further synchronously subjected to the following steps:
forming an insulating layer on said enclosed groove or said enclosed flange;
forming two conductive layers on said insulating layer;
connecting each of two wires between said conductive layer and said at least one LED chip; and
forming a encapsulation on said at least one LED chip, wherein the area formed from said encapsulation is restricted by said enclosed groove or said enclosed flange;
wherein each of said two wires is extended towards the outside of said encapsulation via said corresponding conductive layer.

13. The method for packaging LED chip modules according to claim 11, wherein said second sacrificial layer further defines a sacrificial flange, and said enclosed groove is thus formed on said reflector.

14. The method for packaging LED chip modules according to claim 11, wherein said step of forming a support layer further includes defining a sacrificial groove in said first sacrificial layer, and said enclosed flange is thus formed on said reflector.

15. The method for packaging LED chip modules according to claim 1, wherein said substrate of said at least one LED chip is provided with at least one concave structure, into which said support layer grows.

16. The method for packaging LED chip modules according to claim 1, wherein each of said first sacrificial layer and said second sacrificial layer is a photoresistant layer.

17. A moving fixture, suitable for moving multiple LED chips synchronously, said moving fixture comprising:
an upper molding board having a vacuum chamber;
a lower molding board having multiple through-holes, wherein said through-holes pass through a body of said lower molding board and communicate with said vacuum chamber; and
a carrying disc having multiple accommodating locations, into which said LED chips are placed, wherein said LED chips placed in said carrying disc are adapted to be sucked synchronously by said moving fixture using vacuum suction.

18. The fixture according to claim 17, further comprising a vacuum seal ring, said vacuum seal ring being clamped between said upper molding board and said lower molding board, wherein said vacuum chamber of said upper molding board is located within the enclosing range of said vacuum seal ring.

19. The fixture according to claim 18, wherein said vacuum chamber and a vacuum piping are connected with each other.

20. The fixture according to claim 17, wherein said carrying disc comprises at least one first locator.

21. The fixture according to claim 20, wherein said lower molding board comprises at least one second locator, said second locator being cooperated with said first locator, in such a way that said first and second locators are positioned perpendicularly to each other.

22. The fixture according to claim 17, further comprising:
multiple suction tips corresponding and communicating with respective ones of said through-holes extending outwardly from an external surface of the body of said lower molding board, wherein said LED chips placed in said carrying disc are sucked synchronously by said suction tips using vacuum suction.

23. The fixture according to claim 22, wherein said suction tips and said accommodating locations of said carrying disc are arranged correspondingly with each other in a matrix form.

24. An LED chip module, comprising:
at least one LED chip having a substrate and a plurality of epitaxial layers;
an optical cup having a inside bottom and an upper edge, said optical cup carrying at least one LED chip via said inside bottom;
said upper edge of said optical cup including at least one enclosed groove or at least one enclosed flange surrounding said at least one LED chip;
at least one insulating layer located on said enclosed groove or said enclosed flange;
two conductive layers located on said insulating layer;
two wires, each connected between said corresponding conductive layer and said at least one LED chip; and
an encapsulation structure covering said at least one LED chip, wherein the range formed with said encapsulation structure is restricted by said enclosed groove or said enclosed flange, and each of said two wires extends outside of said encapsulation structure via said corresponding conductive layer.

25. The LED chip module according to claim 24, wherein said optical cup is provided with a reflector and a base, and said substrate of said at least one LED chip is carried by said optical cup via said reflector.

26. The LED chip module according to claim 25, wherein said substrate of said LED chip is provided with at least one concave structure, into which said reflector and said base grow.
